(19) United States
(12) Patent Application Publication
(10) Pub. No.: US 2026/0005213 A1
(43) Pub. Date: Jan. 1, 2026

(54) PACKAGE STRUCTURE AND PREPARATION METHOD THEREOF

(71) Applicant: JCET ADVANCED PACKAGING CO., LTD., JIANGSU (CN)

(72) Inventors: Haijie CHEN, JIANGSU (CN); Jielei XIE, JIANGSU (CN)

(73) Assignee: JCET ADVANCED PACKAGING CO., LTD., JIANGSU (CN)

(21) Appl. No.: 19/251,850

(22) Filed: Jun. 27, 2025

(30) Foreign Application Priority Data
Jun. 27, 2024 (CN) 202410847623.6

(51) Int. Cl. H01L 25/18; H01L 23/00; H01L 23/538; H01L 25/00; H01L 25/065; H10B 80/00; H10D 80/30

(52) U.S. Cl. CPC H01L 25/18; H01L 23/5386; H01L 24/08; H01L 24/16; H01L 25/0657; H01L 25/50; H10B 80/00; H10D 80/30; H01L 2224/08146; H01L 2224/16146; H01L 2224/16225; H01L 2225/06513; H01L 2225/06517; H01L 2225/06541; H01L 2924/1431

(57) ABSTRACT

A package structure and a related preparation method thereof are disclosed. The package structure includes: an interposer; and a logic chip structure and a signal channel structure that are located on a surface of the interposer, where the logic chip structure includes a logic chip on a surface of the interposer and a power supply channel structure on a surface of the logic chip. A power supply layer of the logic chip is close to the power supply channel structure, which is electrically connected to a corresponding conductive structure to achieve power supply. A signal layer of the logic chip is close to the interposer and connected to the corresponding conductive structure to realize signal transmission. In this way, the power supply does not interfere with signals, and a logic error is avoided; and an overall voltage and power consumption of a finished package is significantly reduced.

### CROSS-REFERENCE TO RELATED APPLICATION

This application claims the priority benefit of China application serial no. CN202410847623.6 filed on Jun. 27, 2024. The entirety of the above-mentioned patent application is hereby incorporated by reference herein and made a part of this specification.

### TECHNICAL FIELD

The present disclosure relates to the technical field of packaging, and specifically to a package structure and a preparation method thereof.

### BACKGROUND

With continuous evolution of advanced packaging technologies, wafer-level packaging is becoming increasingly popular. Wafer-level packaging enables higher density integration (including higher density or more functionality) in a limited space, and a complete system function in a single package. As package structures become increasingly complex, there is a rising concern that power supply interferes with signals, which may lead to a logic error that can finally significantly reduce an overall voltage and power consumption of a platform.

### SUMMARY

An objective of the present disclosure is to provide a package structure and a related preparation method thereof to overcome a problem that power supply interferes with signals, which may lead to a logic error that can significantly reduce an overall voltage and power consumption of a platform.

To achieve the foregoing objective, the present disclosure provides a package structure, including: an interposer;
a logic chip structure, a signal channel structure, and a molding layer that are located on a surface of the interposer, where the molding layer is used for packaging the logic chip structure and the signal channel structure, and a side surface that is of the logic chip structure and that is away from the interposer and a side surface that is of the signal channel structure and that is away from the interposer are exposed out of the molding layer; and
conductive structures that are located on the side surface that is of the logic chip structure and that is away from the interposer and the side surface that is of the signal channel structure and that is away from the interposer, where
the logic chip structure includes a logic chip located on the surface of the interposer and a power supply channel structure located on a surface of the logic chip, the logic chip includes a signal layer and a power supply layer, the power supply layer of the logic chip is close to the power supply channel structure and is electrically connected to a corresponding conductive structure through the power supply channel structure to realize power supply, and the signal layer of the logic chip is close to the interposer and is connected to the corresponding conductive structure through the interposer and the signal channel structure to establish a signal connection to realize signal transmission.

Preferably, heights of the logic chip structure and the signal channel structure are the same.

Preferably, the power supply layer of the logic chip includes a plurality of power supply areas, the power supply channel structure includes a substrate and a plurality of conductive pillars penetrating the substrate, and two ends of each conductive pillar are respectively connected to a corresponding power supply area and a corresponding conductive structure.

Preferably, the logic chip and the power supply channel structure are connected through a first hybrid bonding layer.

Preferably, the signal channel structure includes at least one signal channel chip stacked, and adjacent signal channel chips are connected through a second hybrid bonding layer.

Preferably, the package structure further includes:
a memory chip structure and a guide channel structure that are located on the surface of the interposer, the molding layer is further used for molding the memory chip structure and the guide channel structure, a side surface that is of the guide channel structure and that is away from the interposer is exposed out of the molding layer, and a conductive structure is arranged on the side surface that is of the guide channel structure and that is away from the interposer, where
the memory chip structure is electrically connected to a corresponding conductive structure through the interposer and the guide channel structure to realize power supply, and the memory chip structure is connected to the corresponding conductive structure through the interposer, the signal layer of the logic chip, and the signal channel structure to establish a signal connection to realize signal transmission.

Preferably, heights of the logic chip structure, the signal channel structure, the guide channel structure, and the memory chip structure are the same.

Preferably, the guide channel structure includes at least one guide channel chip stacked, and adjacent guide channel chips are connected through a third hybrid bonding layer.

Preferably, the logic chip structure, the signal channel structure, the memory chip structure, and the guide channel structure are connected to the interposer through a first solder bump.

Preferably, the memory chip structure includes at least one memory chip stacked, and adjacent memory chips are connected through a second solder bump.

Preferably, a side surface of that is of the memory chip structure and that is away from the interposer is exposed out of the molding layer, and both the side surface that is of the memory chip structure and that is away from the interposer and a side surface that is of the molding layer and that is away from the interposer have a conductive structure.

Correspondingly, the present disclosure further provides a preparation method for a package structure, which includes:
forming an interposer;
arranging a logic chip structure and a signal channel structure on a surface of the interposer;
molding the logic chip structure and the signal channel structure with a molding material to form a molding layer, where a side surface that is of the logic chip structure and that is away from the interposer and a side surface that is of the signal channel structure and that is away from the interposer are exposed out of the molding layer; and
arranging conductive structures on the side surface that is of the logic chip structure and that is away from the interposer and the side surface that is of the signal channel structure and that is away from the interposer, where
the logic chip structure includes a logic chip located on the surface of the interposer and a power supply channel structure located on a surface of the logic chip, the logic chip includes a signal layer and a power supply layer, the power supply layer of the logic chip is close to the power supply channel structure and is electrically connected to a corresponding conductive structure through the power supply channel structure to realize power supply, the signal layer of the logic chip is close to the interposer and is connected to the corresponding conductive structure through the interposer and the signal channel structure to establish a signal connection to realize signal transmission.

Preferably, the power supply layer of the logic chip includes a plurality of power supply areas, the power supply channel structure includes a substrate and a plurality of conductive pillars penetrating the substrate, and two ends of each conductive pillar are respectively connected to a corresponding power supply area and a corresponding conductive structure.

Preferably, the signal channel structure includes at least one signal channel chip stacked, and adjacent signal channel chips are connected through a second hybrid bonding layer.

Preferably, the process of arranging the logic chip structure and the signal channel structure on the surface of the interposer further includes: arranging the memory chip structure and the guide channel structure on the surface of the interposer; a subsequent process of forming the molding layer further includes: molding the memory chip structure and the guide channel structure with a molding material, and where a side surface that is of the guide channel structure and that is away from the interposer is exposed out of the molding layer; and a subsequent process of arranging the conductive structure further includes: arranging the conductive structure on the side surface that is of the guide channel structure and that is away from the interposer, where the memory chip structure is electrically connected to a corresponding conductive structure through the interposer and the guide channel structure to realize power supply, and the memory chip structure is connected to the corresponding conductive structure through the interposer, the signal layer of the logic chip, and the signal channel structure to establish a signal connection to realize signal transmission.

Preferably, the guide channel structure includes at least one guide channel chip stacked, and adjacent guide channel chips are connected through a third hybrid bonding layer.

Preferably, the step of arranging the logic chip structure, the signal channel structure, the memory chip structure, and the guide channel structure on the surface of the interposer includes:
arranging the logic chip structure, the signal channel structure, the memory chip structure, and the guide channel structure on the surface of the interposer through a first solder bump.

The present disclosure has the following beneficial effects:

The present disclosure provides a package structure and a related preparation method thereof. The package structure includes: an interposer; and a logic chip structure and a signal channel structure that are located on a surface of the interposer, where the logic chip structure includes a logic chip located on a surface of the interposer and a power supply channel structure located on a surface of the logic chip. A power supply layer of the logic chip is arranged close to the power supply channel structure, and the power supply channel structure is electrically connected to a corresponding conductive structure, so as to achieve power supply. A signal layer of the logic chip is arranged close to the interposer, and is connected to the corresponding conductive structure to realize signal transmission. In this way, a problem that the power supply interferes with signals is solved, and a logic error is avoided; and an overall voltage and power consumption can be significantly reduced, so that performance of a finished package is improved.

### BRIEF DESCRIPTION OF DRAWINGS

FIG. 1 to FIG. 6 are schematic diagrams of a preparation process of a package structure according to some embodiments of the present disclosure.

### DETAILED DESCRIPTION OF EMBODIMENTS

The following clearly and completely describes the technical solutions in the embodiments of the present disclosure with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

It should be understood that, as used herein, terms such as “first”, “second”, and “third” describe various components, assemblies, regions, layers, and/or segments, which shall not be limited by such terms. These terms can be used simply to distinguish one component, assembly, region, layer, or segment from another. For example, the terms “first”, “second”, and “third” are used herein without implying an order or a sequence, unless clearly indicated by the context.

For ease of description, spatially relative terms may be used herein to describe a relationship of one component or feature to other components or features as illustrated in the accompanying drawings. It should be understood that the spatially relative terms are intended to encompass different orientations of the device in use or operation in addition to the orientation depicted in the accompanying drawings.

In this application, unless otherwise expressly specified and defined, terms such as “connect” and “connected to” should be understood in a broad sense. For example, unless otherwise expressly defined, a “connection” may be a fixed connection, may be a detachable connection, or may be an integrated connection; or may be a mechanical connection or an electrical connection; or may be a direct connection, or an indirect connection through an intermediate medium; or may be an inner connection between two components, or interaction between two components. A person of ordinary skill in the art may understand specific meanings of the foregoing terms in this application according to specific cases.

In the description of this specification, descriptions with reference to the term such as “an embodiment”, “some embodiments”, “example”, “specific example”, or “some examples” mean that specific features, structures, materials, or characteristics described with reference to the embodiment or example are included in at least one embodiment or example of this application. In this specification, illustrative expressions of these terms do not necessarily refer to the same embodiment or example. In addition, the specific feature, structure, material, or characteristic described may be combined in any suitable manner in any one or more embodiments or examples. In addition, without mutual contradiction, those skilled in the art may incorporate and combine different embodiments or examples and features of the different embodiments or examples described in this specification. It should be noted that the terms “including”, “having”, or any other variant thereof in this application are intended to cover a non-exclusive inclusion.

Referring to FIG. 5, some embodiments of the present disclosure provide a package structure, including:
an interposer 100;
a logic chip structure 220, a signal channel structure 210, and a molding layer 300 that are located on a surface of the interposer 100, where the molding layer 300 is used for packaging the logic chip structure 220 and the signal channel structure 210, and a side surface 2201 that is of the logic chip structure and that is away from the interposer and a side surface 2101 that is of the signal channel structure and that is away from the interposer are exposed out of the molding layer 300; and
a conductive structure 400 that is located on the side surface 2201 that is of the logic chip structure and that is away from the interposer and the side surface 2101 that is of the signal channel structure and that is away from the interposer, where
the logic chip structure 220 includes a logic chip 221 located on the surface of the interposer 100 and a power supply channel structure 222 located on a surface of the logic chip 221, the logic chip 221 includes a signal layer 2211 and a power supply layer 2212, the power supply layer 2212 of the logic chip is close to the power supply channel structure 222 and is electrically connected to a corresponding conductive structure 400 through the power supply channel structure 222 to realize power supply, the signal layer 2211 of the logic chip is close to the interposer 100 and is connected to the corresponding conductive structure 400 through the interposer 100 and the signal channel structure 210 to establish a signal connection to realize signal transmission. This results in a relatively large spacing and a relatively low probability of crosstalk during power supply and signal transmission.

In some embodiments of the present disclosure, the power supply layer 2212 of the logic chip is close to the power supply channel structure 222, the power supply channel structure 221 is electrically connected to the corresponding conductive structure 400 to realize power supply, the signal layer 2211 of the logic chip is close to the interposer 100 and is connected to the corresponding conductive structure 400 through the interposer 100 and the signal channel structure 210 to establish a signal connection to realize signal transmission. In this way, a problem that the power supply interferes with signals is solved, and a logic error is avoided; and an overall voltage and power consumption can be significantly reduced, so that performance of a finished package is improved.

In some embodiments, the interposer 100 may be a substrate, and the substrate may be a resin substrate, a ceramic substrate, a glass substrate, a silicon substrate, or a printed circuit board (PCB). In some embodiments, the interposer 100 includes an insulation structure and a conductive line 110 extending through the insulation structure. In some embodiments, the conductive circuit 110 has a first metal wiring 111, and the first metal wiring 111 is used as a signal transmission line for connecting the signal layer 2211 and the signal channel structure 210 of the logic chip structure. In some embodiments, a solder pad is arranged on the surface of the interposer, and a corresponding first solder bump 250 is arranged on a surface of the solder pad. In some embodiments, a material of the solder pad may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. In some embodiments, a material of the first solder bump 250 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

In some embodiments, that the side surface 2101 that is of the signal channel structure and that is away from the interposer is exposed out of the molding layer 300 is specifically that the side surface that is of the power supply channel structure 222 and that is away from the logic chip 221 is exposed out of the molding layer 300. In some embodiments, heights of the logic chip structure 220 and the signal channel structure 210 are the same, and the height of the signal channel structure 210 may be set according to the height of the logic chip structure 220.

In some embodiments, the logic chip 221 may include a gate array, a cell substrate array, an embedded array, a structured application specific integrated circuit (ASIC), a field programmable gate array (FPGA), a complex programmable logic device (CPLD), a central processing unit (CPU), a processing unit (XPU), a micro processing unit (MPU), a micro controller unit (MCU), a logic integrated circuit (IC), an application processor (AP), a display driver IC (DDI), a radio frequency (RF) chip, or a complementary metal-oxide-semiconductor (CMOS) image sensor.

The signal layer 2211 and the power supply layer 2212 of the logic chip adopted in some embodiments of the present disclosure are arranged hierarchically; the power supply layer 2212 of the logic chip is close to the power supply channel structure 222 and is electrically connected to the corresponding conductive structure 400 (that is, the conductive structure 400 that is located on one side surface 2201 of the logic chip structure and that is away from the interposer) through the power supply channel structure 222 to realize power supply; and the signal layer 2211 of the logic chip is close to the interposer 100 and is connected to the corresponding conductive structure 400 (that is, the conductive structure 400 that is located on one side surface of the signal channel structure and that is away from the interposer 2101) through the interposer 100 and the signal channel structure 210 to establish a signal connection to realize signal transmission.

In some embodiments, the power supply layer 2212 of the logic chip includes a plurality of power supply areas, the power supply channel structure 222 includes a substrate 2222 and a plurality of conductive pillars 2221 penetrating the substrate 2222, and two ends of each conductive pillar 2221 are respectively connected to a corresponding power supply area and a corresponding conductive structure 400. In some embodiments, the substrate 2222 may be a silicon substrate, a polymer substrate, a silicon substrate at an insulation layer, a silicon carbide base, a composite substrate, or the like In some embodiments, the conductive pillar 2221 may also be referred to as a through-silicon via. In some embodiments, a material of the substrate 2222 may also be a molding material. In some embodiments, the molding material may be epoxy resin, polyimide resin, benzocyclobutene resin, or polybenzoxazole resin.

In some embodiments, the logic chip 221 and the power supply channel structure 222 are connected through a first hybrid bonding layer 203. In some embodiments, the first hybrid bonding layer 203 includes an insulation layer and a conductive layer located at the insulation layer, and each power supply area of the power supply layer 2212 is aligned with a corresponding conductive pillar 2221 and is connected through a conductive layer of the first hybrid bonding layer 203.

In some embodiments, the signal channel structure 210 includes at least one signal channel chip stacked, and a specific number may be determined according to the height of the logic chip structure 220, so that heights of the logic chip structure 220 and the signal channel structure 210 are the same; and each signal channel chip has a plurality of penetrating signal channels 211, a material of the signal channel 211 is metal such as copper, silver, nickel, gold, aluminum, or an alloy thereof, and adjacent signal channel chips are connected through a second hybrid bonding layer 212. In some embodiments, the second hybrid bonding layer 212 includes an insulation layer and a conductive layer located at the insulation layer, and signal channels 211 of signal channel chips at adjacent layers are aligned with each other and connected through the conductive layer of the second hybrid bonding layer 212.

Referring to FIG. 5, some embodiments of the present disclosure have taken into account packaging requirements of a memory chip, the package structure provided further includes a memory chip structure 230 and a guide channel structure 240 located on the surface of the interposer 100, and the molding layer 300 is also used for molding the memory chip structure 230 and the guide channel structure 240, and a side surface 2401 that is of the guide channel structure and that is away from the interposer is exposed out of the molding layer 300, and a conductive structure 400 is arranged on the side surface 2401 that is of the guide channel structure and that is away from the interposer.

The memory chip structure 230 is electrically connected to a corresponding conductive structure 400 (that is, the conductive structure 400 on one side surface that is of the guide channel structure and that is away from the interposer 2401) through the interposer 100 and the guide channel structure 240; and the memory chip structure 230 is connected to a corresponding conductive structure 400 (that is, the conductive structure 400 on one side surface that is of the signal channel structure and that is away from the interposer 2101) through the interposer 100, the signal layer 2211 of the logic chip, and the signal channel structure 210 to realize signal transmission.

In some embodiments, the conductive wire 110 further includes a second metal wiring 112 and a third metal wiring 113, the second metal wiring 112 is used as a signal interconnection wire for connecting the logic chip structure 220 and the memory chip structure 230, and the third metal wiring 113 is used as a power line for connecting the memory chip structure 230 and the guide channel structure 240.

In some embodiments, heights of the logic chip structure 220, the signal channel structure 210, the guide channel structure 240, and the memory chip structure 230 are the same.

In some embodiments, the memory chip structure 230 includes at least one memory chip stacked, and the stacked memory chip further includes at least one memory chip with an adjustable thickness. As shown in FIG. 3, the memory chip with an adjustable thickness is arranged on one side that is of the memory chip structure and that is away from the interposer, a specific number of memory chips can be determined according to actual demand, and adjacent memory chips are connected through a second solder bump 231. In some embodiments, the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive CMOS (RERAM)). In some embodiments, a material of the second solder bump 231 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

In some embodiments, the guide channel structure 240 includes at least one guide channel chip stacked, and a specific number of chips of the guide channel structure 240, a height of the logic chip structure, and a specific number of chips of the signal channel structure may be determined according to the height of the memory chip structure 230, so that heights of the logic chip structure 220, the signal channel structure 210, the guide channel structure 240, and the memory chip structure 230 are the same. In some embodiments, the guide channel chip includes a plurality of penetrating guide channels 241, a material of the diversion channel 241 is metal such as copper, silver, nickel, gold, aluminum, or an alloy thereof, and adjacent guide channel chips are connected through a third hybrid bonding layer 242. In some embodiments, the third hybrid bonding layer 242 includes an insulation layer and a conductive layer located at the insulation layer, and guide channels 241 of the guide channel chips at the adjacent layers are aligned with each other and connected through the conductive layer of the third hybrid bonding layer 242.

In some embodiments, the logic chip structure 220, the signal channel structure 210, the memory chip structure 230, and the guide channel structure 240 are connected to the interposer 100 through a first solder bump 250.

In some embodiments, the side surface 2301 that is of the memory chip structure and that is away from the interposer is exposed out of the molding layer 300, conductive structures 400 is arranged on the side surface 2301 that is of the memory chip structure and that is away from the interposer and the side surface 3001 that is of the molding layer and that is away from the interposer, and the conductive structures 400 is arranged on the side surface 2301 that is of the memory chip structure and that is away from the interposer and the side surface 3001 that is of the molding layer and that is away from the interposer are used for support. A solder mask layer is also arranged on the side surface 3001 that is of the molding layer and that is away from the interposer, and the solder mask layer is a PI layer, silicon nitride, or the like In some embodiments, a material of the molding layer 300 may be epoxy resin, polyimide resin, benzocyclobutene resin, or polybenzoxazole resin, and the forming process may be an injection molding process or a transfer molding process. In some embodiments, the conductive structure 400 may be a structure such as a solder ball or a conductive pillar, and a material of the solder ball may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. A material of the conductive pillar is metal such as copper, silver, nickel, gold, aluminum, or an alloy thereof.

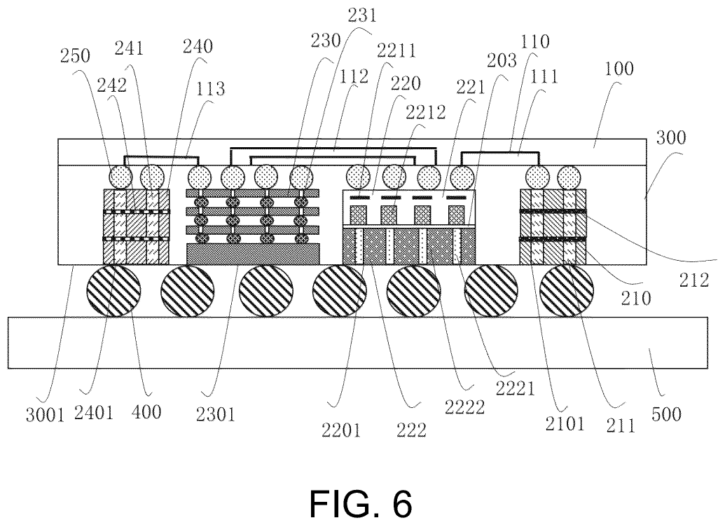

Referring to FIG. 6, a package structure provided in some embodiments of the present disclosure further includes a substrate 500, and the conductive structure 400 is located on a surface of the substrate 500, the memory chip structure 230 and the guide channel structure 240 can be finally connected to the substrate 500 through the conductive structure 400. This results in a relatively large spacing and a relatively low probability of crosstalk during power supply and signal transmission. In some embodiments, the substrate 500 may be a resin substrate, a ceramic substrate, a glass substrate, a silicon substrate, or a printed circuit board (PCB).

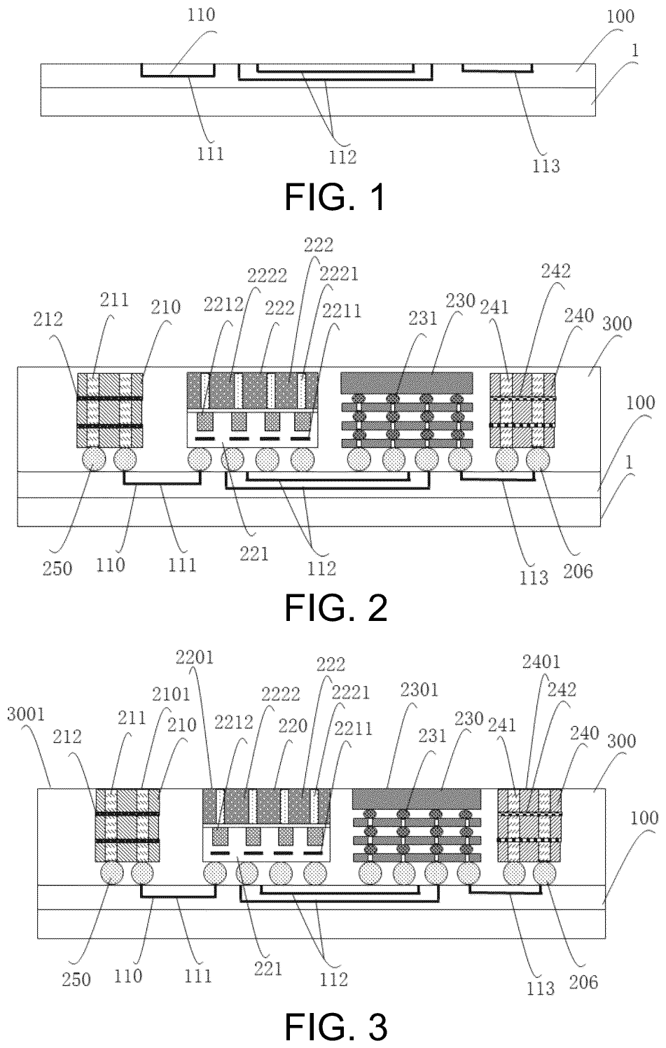

Based on a same invention concept, some embodiments of the present disclosure further provide a preparation method for a package structure, including: Referring to FIG. 1, a temporary carrier board 1 is provided, and an interposer 100 is formed on a surface of the temporary carrier board 1. In some embodiments, the interposer 100 may be a substrate, and the substrate may be a resin substrate, a ceramic substrate, a glass substrate, a silicon substrate, or a printed circuit board (PCB). In some embodiments, the interposer 100 includes an insulation structure and a conductive line 110 extending through the insulation structure. In some embodiments, the conductive circuit 110 has a first metal wiring 111, and the first metal wiring 111 is used as a signal transmission line for connecting the signal layer 2211 and the signal channel structure 210 of the logic chip structure. In some embodiments, a solder pad is arranged on the surface of the interposer. In some embodiments, a material of the solder pad may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

Referring to FIG. 2, a logic chip structure 220 and a signal channel structure 210 are arranged on a surface of the interposer 100. In some embodiments, the logic chip structure 220 and the signal channel structure 210 may be arranged on the surface of the interposer 100 through a corresponding first solder bump 250. In some embodiments, heights of the logic chip structure 220 and the signal channel structure 210 are the same, and the height of the signal channel structure 210 may be set according to the height of the logic chip structure 220. In some embodiments, the logic chip structure 220 includes a logic chip 221 located on the surface of the interposer 100 and a power supply channel structure 222 located on a surface of a logic chip 221, the logic chip 221 includes a signal layer 2211 and a power supply layer 2212, the signal layer 2211 and the power supply layer 2212 are arranged hierarchically, the power supply layer 2212 of the logic chip is close to the power supply channel structure 222 and is electrically connected to a corresponding conductive structure through the power supply channel structure 222 to realize power supply; and the signal layer 2211 of the logic chip is close to the interposer 100 and is connected to the signal channel structure 210 through the interposer 100. In some embodiments, the logic chip 221 may include a gate array, a cell substrate array, an embedded array, a structured application specific integrated circuit (ASIC), a field programmable gate array (FPGA), a complex programmable logic device (CPLD), a central processing unit (CPU), a processing unit (XPU), a micro processing unit (MPU), a micro controller unit (MCU), a logic integrated circuit (IC), an application processor (AP), a display driver IC (DDI), a radio frequency (RF) chip, or a complementary metal-oxide-semiconductor (CMOS) image sensor. In some embodiments, a material of the first solder bump 250 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

In some embodiments, the logic chip 221 and the power supply channel structure 222 are connected through a first hybrid bonding layer 203. In some embodiments, the power supply layer 2212 of the logic chip includes a plurality of power supply areas, and the power supply channel structure 222 includes a substrate 2222 and a plurality of conductive pillars 2221 penetrating through the substrate 2222. In some embodiments, the first hybrid bonding layer 203 includes an insulation layer and a conductive layer located at the insulating layer, and each power supply area of the power supply layer 2212 is aligned with a corresponding conductive pillar 2221 and is connected through a conductive layer of the first hybrid bonding layer 203. In some embodiments, the substrate 2222 may be a silicon substrate, a polymer substrate, a silicon substrate at an insulation layer, a silicon carbide base, a composite substrate, or the like In some embodiments, the conductive pillar 2221 may also be referred to as a through-silicon via. In some embodiments, a material of the substrate 2222 may also be a molding material. In some embodiments, the molding material may be epoxy resin, polyimide resin, benzocyclobutene resin, or polybenzoxazole resin.

In some embodiments, the signal channel structure 210 includes at least one signal channel chip stacked, and a specific number may be determined according to the height of the logic chip structure 220, so that heights of the logic chip structure 220 and the signal channel structure 210 are the same; and each signal channel chip has a plurality of penetrating signal channels 211, a material of the signal channel 211 is metal such as copper, silver, nickel, gold, aluminum, or an alloy thereof, and adjacent signal channel chips are connected through a second hybrid bonding layer 212. In some embodiments, the second hybrid bonding layer 212 includes an insulation layer and a conductive layer located at the insulation layer, and signal channels 211 corresponding to adjacent layer signal channel chips are aligned with each other and connected through a conductive layer of the second hybrid bonding layer 212.

In some embodiments, the process of arranging the logic chip structure 220 and the signal channel structure 210 on the surface of the interposer 100 further includes: arranging a memory chip structure 230 and a guide channel structure 240 on the surface of the interposer 100. In some embodiments, the memory chip structure 230 is electrically connected to the guide channel structure 240 through the interposer 100 and; and the memory chip structure 230 is connected to the signal channel structure 210 through the interposer 100 and the signal layer 2211 of the logic chip. In some embodiments, the conductive wire 110 further includes a second metal wiring 112 and a third metal wiring 113, the second metal wiring 112 is used as a signal interconnection wire for connecting the logic chip structure 220 and the memory chip structure 230, and the third metal wiring 113 is used as a power line for connecting the memory chip structure 230 and the guide channel structure 240. In some embodiments, the memory chip structure 230 and the guide channel structure 240 may be arranged on the surface of the interposer 100 through a first solder bump 250. In some embodiments, heights of the logic chip structure 220, the signal channel structure 210, the guide channel structure 240, and the memory chip structure 230 are the same. In some embodiments, the memory chip structure 230 includes at least one memory chip stacked, a specific number of the memory chips may be determined according to actual requirements, and adjacent memory chips are connected through a second solder bump 231. In some embodiments, the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive CMOS (RERAM)). In some embodiments, a material of the second solder bump 231 may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. In some embodiments, the guide channel structure 240 includes at least one guide channel chip stacked, and a specific number of chips of the guide channel structure 240, a height of the logic chip structure 220, and a specific number of chips of the signal channel structure 210 may be determined according to the height of the memory chip structure 230, so that heights of the logic chip structure 220, the signal channel structure 210, the guide channel structure 240, and the memory chip structure 230 are the same; and the guide channel chip has a plurality of penetrating guide channels 241, a material of the guide channel 241 is metal such as copper, silver, nickel, gold, aluminum, or an alloy thereof, and adjacent guide channel chips are connected through a third hybrid bonding layer 242. In some embodiments, the third hybrid bonding layer 242 includes an insulation layer and a conductive layer located at the insulation layer, and guide channels 241 of the guide channel chips at the adjacent layers are aligned with each other and connected through the conductive layer of the third hybrid bonding layer 242.

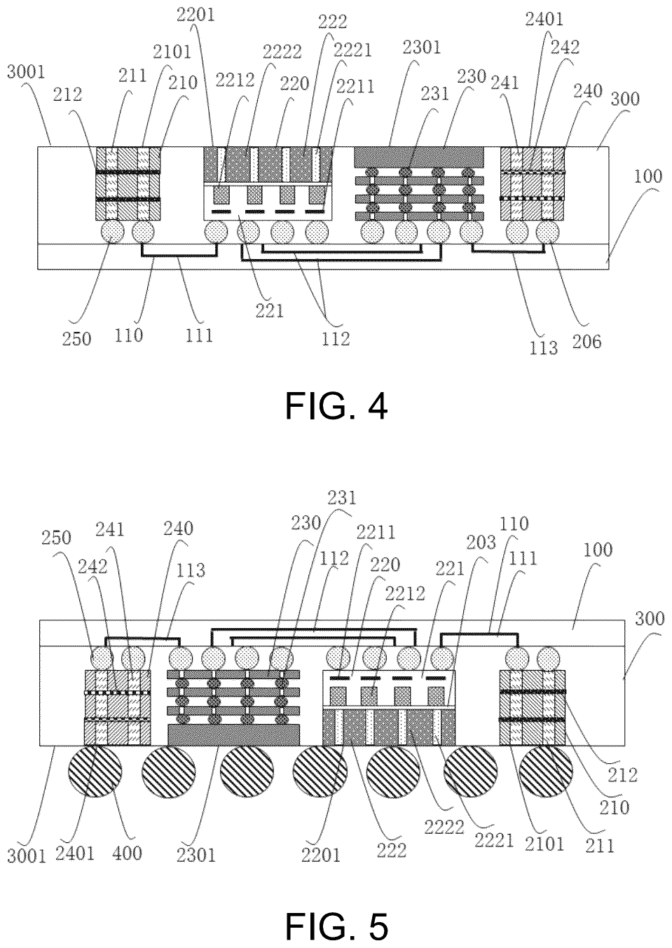

Referring to FIG. 3, the logic chip structure 220 and the signal channel structure 210 are molded with a molding material 300 to form a molding layer 300; and then the molding layer 300 may be ground (as shown in FIG. 4), so that the side surface 2201 that is of the logic chip structure and that is away from the interposer and the side surface 2101 that is of the signal channel structure and that is away from the interposer are exposed out of the molding layer 300. In some embodiments, that the side surface 2101 that is of the signal channel structure and that is away from the interposer is exposed out of the molding layer 300 is specifically that the side surface that is of the power supply channel structure 222 and that is away from the logic chip 221 is exposed out of the molding layer 300. In some embodiments, when a memory chip structure 230 and a guide channel structure 240 are also arranged on the surface of the interposer 100, the process of the molding layer 300 further includes molding the memory chip structure 230 and the guide channel structure 240 with a molding material, where a side surface 2401 that is of the guide channel structure and that is away from the interposer is exposed out of the molding layer 300. In some embodiments, the side surface 2301 that is of the memory chip structure and that is away from the interposer is exposed out of the molding layer 300. In some embodiments, a material of the molding layer 300 may be epoxy resin, polyimide resin, benzocyclobutene resin, or polybenzoxazole resin, and the forming process may be an injection molding process or a transfer molding process.

Referring to FIG. 5, conductive structures 400 are arranged on the side surface 2201 that is of the logic chip structure and that is away from the interposer and the side surface 2101 that is of the signal channel structure and that is away from the interposer, so that the memory chip structure 230 is electrically connected to a corresponding conductive structure 400 through the interposer 100 and the guide channel structure 240, and the memory chip structure 230 is connected to the corresponding conductive structure 400 through the interposer 100, the signal layer 2211 of the logic chip, and the signal channel structure 210 to establish a signal connection. In some embodiments, when a memory chip structure 230 and a guide channel structure 240 are also arranged on the surface of the interposer 100, and the side surface 2401 that is of the guide channel structure and that is away from the interposer is exposed out of the molding layer 300, the process of arranging the conductive structure 400 further includes: arranging the conductive structure 400 on the side surface 2401 that is of the guide channel structure and that is away from the interposer. In some embodiments, the side surface 2301 that is of the memory chip structure and that is away from the interposer is exposed out of the molding layer 300, a solder mask layer is also arranged on the side surface 2301 that is of the memory chip structure and that is away from the interposer, and the solder mask layer can make the solder ball form a good connection with a back surface of a memory chip. Conductive structures 400 may also be arranged on the side surface 2301 that is of the memory chip structure and that is away from the interposer and the side surface 3001 that is of the molding layer and that is away from the interposer for support and heat dissipation. In some embodiments, the conductive structure 400 may be a structure such as a solder ball or a conductive pillar, and a material of the solder ball may be one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. A material of the conductive pillar is metal such as copper, silver, nickel, gold, aluminum, or an alloy thereof.

In some embodiments, referring to FIG. 6, in the structure formed above, the conductive structure 400 may be arranged on the surface of the substrate 500, so that the memory chip structure 230 and the guide channel structure 240 can be finally connected to the substrate 500 through the conductive structure 400. This results to form different routines for power supply and signal transmission, the crosstalk is decreased In some embodiments, the substrate 500 may be a resin substrate, a ceramic substrate, a glass substrate, a silicon substrate, or a printed circuit board (PCB).

The signal layer 2211 and the power supply layer 2212 of the logic chip adopted in some embodiments of the present disclosure are arranged hierarchically; the power supply layer 2212 of the logic chip is close to the power supply channel structure 222 and is electrically connected to the corresponding conductive structure 400 (that is, the conductive structure 400 that is located on one side surface 2201 of the logic chip structure and that is away from the interposer) through the power supply channel structure 222 to realize power supply; and the signal layer 2211 of the logic chip is close to the interposer 100 and is connected to the corresponding conductive structure 400 (that is, the conductive structure 400 that is located on one side surface of the signal channel structure and that is away from the interposer 2101) through the interposer 100 and the signal channel structure 210 to establish a signal connection to realize signal transmission. In this way, a problem that the power supply interferes with signals is solved, and a logic error is avoided; and an overall voltage and power consumption can be significantly reduced, so that performance of a finished package is improved.

Some embodiments of the present disclosure also take into account packaging requirements of a memory chip, the memory chip structure 230 and the guide channel structure 240 are arranged on the surface of the interposer 100, and the memory chip structure 230 is electrically connected to a corresponding conductive structure 400 (that is, the conductive structure 400 on one side surface that is of the guide channel structure and that is away from the interposer 2401) through the interposer 100 and the guide channel structure 240; and the memory chip structure 230 is connected to a corresponding conductive structure 400 (that is, the conductive structure 400 on one side surface that is of the signal channel structure and that is away from the interposer 2101) through the interposer 100, the signal layer 2211 of the logic chip, and the signal channel structure 210 to realize signal transmission.

The present disclosure has been described with reference to the preferred embodiments, which are not used to limit the present disclosure. Those skilled in the art can make possible variations and modifications to the present disclosure using the disclosed methods and technical contents without departing from the spirit and scope of the present disclosure; and therefore, any simple modifications, equivalent changes and modifications made to the foregoing embodiments according to the technical spirit of the present disclosure without departing from the content of the technical solutions of the present disclosure shall fall within the protection scope of the technical solutions of the present disclosure.

What is claimed is:

1. A package structure, comprising:
an interposer;
a logic chip structure, a signal channel structure, and a molding layer that are located on a surface of the interposer, wherein the molding layer is used for packaging the logic chip structure and the signal channel structure, and a side surface that is of the logic chip structure and that is away from the interposer and a side surface that is of the signal channel structure and that is away from the interposer are exposed out of the molding layer; and
conductive structures that are located on the side surface that is of the logic chip structure and that is away from the interposer and the side surface that is of the signal channel structure and that is away from the interposer, wherein
the logic chip structure comprises a logic chip located on the surface of the interposer and a power supply channel structure located on a surface of the logic chip, the logic chip comprises a signal layer and a power supply layer, the power supply layer of the logic chip is close to the power supply channel structure and is electrically connected to a corresponding conductive structure through the power supply channel structure to realize power supply, and the signal layer of the logic chip is close to the interposer and is connected to the corresponding conductive structure through the interposer and the signal channel structure to establish a signal connection to realize signal transmission.

2. The package structure according to claim 1, wherein heights of the logic chip structure and the signal channel structure are the same.

3. The package structure according to claim 1, wherein the power supply layer of the logic chip comprises a plurality of power supply areas, the power supply channel structure comprises a substrate and a plurality of conductive pillars penetrating the substrate, and two ends of each conductive pillar are respectively connected to a corresponding power supply area and a corresponding conductive structure.

4. The package structure according to claim 1, wherein the logic chip and the power supply channel structure are connected through a first hybrid bonding layer.

5. The package structure according to claim 1, wherein the signal channel structure comprises at least one signal channel chip stacked, and adjacent signal channel chips are connected through a second hybrid bonding layer.

6. The package structure according to claim 1, further comprising:
a memory chip structure and a guide channel structure that are located on the surface of the interposer, the molding layer is further used for molding the memory chip structure and the guide channel structure, a side surface that is of the guide channel structure and that is away from the interposer is exposed out of the molding layer, and a conductive structure is arranged on the side surface that is of the guide channel structure and that is away from the interposer, wherein
the memory chip structure is electrically connected to a corresponding conductive structure through the interposer and the guide channel structure to realize power supply, and the memory chip structure is connected to the corresponding conductive structure through the interposer, the signal layer of the logic chip, and the signal channel structure to establish a signal connection to realize signal transmission.

7. The package structure according to claim 6, wherein heights of the logic chip structure, the signal channel structure, the guide channel structure, and the memory chip structure are the same.

8. The package structure according to claim 6, wherein the guide channel structure comprises at least one guide channel chip stacked, and adjacent guide channel chips are connected through a third hybrid bonding layer.

9. The package structure according to claim 6, wherein the logic chip structure, the signal channel structure, the memory chip structure, and the guide channel structure are connected to the interposer through a first solder bump.

10. The package structure according to claim 6, wherein the memory chip structure comprises at least one memory chip stacked, and adjacent memory chips are connected through a second solder bump.

11. The package structure according to claim 6, wherein a side surface of that is of the memory chip structure and that is away from the interposer is exposed out of the molding layer, and both the side surface that is of the memory chip structure and that is away from the interposer and a side surface that is of the molding layer and that is away from the interposer have a conductive structure.

12. A preparation method for a package structure, comprising:
forming an interposer;
arranging a logic chip structure and a signal channel structure on a surface of the interposer;
molding the logic chip structure and the signal channel structure with a molding material to form a molding layer, wherein a side surface that is of the logic chip structure and that is away from the interposer and a side surface that is of the signal channel structure and that is away from the interposer are exposed out of the molding layer; and
arranging conductive structures on the side surface that is of the logic chip structure and that is away from the interposer and the side surface that is of the signal channel structure and that is away from the interposer, wherein
the logic chip structure comprises a logic chip located on the surface of the interposer and a power supply channel structure located on a surface of the logic chip, the logic chip comprises a signal layer and a power supply layer, the power supply layer of the logic chip is close to the power supply channel structure and is electrically connected to a corresponding conductive structure through the power supply channel structure to realize power supply, the signal layer of the logic chip is close to the interposer and is connected to the corresponding conductive structure through the interposer and the signal channel structure to establish a signal connection to realize signal transmission.

13. The preparation method for a package structure according to claim 12, wherein the power supply layer of the logic chip comprises a plurality of power supply areas, the power supply channel structure comprises a substrate and a plurality of conductive pillars penetrating the substrate, and two ends of each conductive pillar are respectively connected to a corresponding power supply area and a corresponding conductive structure.

14. The preparation method for a package structure according to claim 12, wherein the signal channel structure comprises at least one signal channel chip stacked, and adjacent signal channel chips are connected through a second hybrid bonding layer.

15. The preparation method for a package structure according to claim 12, wherein the process of arranging the logic chip structure and the signal channel structure on the surface of the interposer further comprises: arranging the memory chip structure and the guide channel structure on the surface of the interposer; a subsequent process of forming the molding layer further comprises: molding the memory chip structure and the guide channel structure with a molding material, and wherein a side surface that is of the guide channel structure and that is away from the interposer is exposed out of the molding layer; and a subsequent process of arranging the conductive structure further comprises: arranging the conductive structure on the side surface that is of the guide channel structure and that is away from the interposer, wherein
the memory chip structure is electrically connected to a corresponding conductive structure through the interposer and the guide channel structure to realize power supply, and the memory chip structure is connected to the corresponding conductive structure through the interposer, the signal layer of the logic chip, and the signal channel structure to establish a signal connection to realize signal transmission.

16. The preparation method for a chip package structure according to claim 15, wherein the guide channel structure comprises at least one guide channel chip stacked, and adjacent guide channel chips are connected through a third hybrid bonding layer.

17. The preparation method for a package structure according to claim 15, wherein the step of arranging the logic chip structure, the signal channel structure, the memory chip structure, and the guide channel structure on the surface of the interposer comprises:
arranging the logic chip structure, the signal channel structure, the memory chip structure, and the guide channel structure on the surface of the interposer through a first solder bump.
